(19) United States
(12) Patent Application Publication
(10) Pub. No.: US 2025/0058520 A1
(43) Pub. Date: Feb. 20, 2025

(54) FUNCTIONALIZATION OF MICROSCALE 3D-PRINTED POLYMER STRUCTURES WITH NANOSCALE VAPOR DEPOSITED ELECTRONIC LAYERS

(71) Applicant: TRUSTEES OF DARTMOUTH COLLEGE, Hanover, NH (US)

(72) Inventors: William SCHEIDELER, West Lebanon, NH (US); Julia HUDDY, West Lebanon, NH (US)

(21) Appl. No.: 18/685,671

(22) PCT Filed: Aug. 22, 2022
(86) PCT No.: PCT/US22/40999

§ 371 Date: Feb. 22, 2024

Related U.S. Application Data
(60) Provisional application No. 63/235,799, filed on Aug. 22, 2021.

(51) Int. Cl. B29C 64/30; B33Y 40/20; C23C 16/34; C23C 16/40; C23C 16/455

(52) U.S. Cl. CPC B29C 64/30; B33Y 40/20; C23C 16/345; C23C 16/40; C23C 16/45525

(57) ABSTRACT

A 3D printed, complex polymer structure can include a seed layer on the polymer structure. A thin film can be disposed on the seed layer. The seed layer can be an oxide, a nitride, or an oxynitride. The thin film can be an oxide, dielectric, semiconductor, or conductor. The polymer structure can be a lattice structure, cantilever, beam, or other shapes.

### CROSS-REFERENCE TO RELATED APPLICATIONS

This application claims priority to the provisional patent application filed Aug. 22, 2021 and assigned U.S. App. No. 63/235,799, the disclosure of which is hereby incorporated by reference.

### STATEMENT REGARDING FEDERALLY-SPONSORED RESEARCH OR DEVELOPMENT

This invention was made with government support under contract AWD00011316 awarded by the National Science Foundation. The government has certain rights in the invention.

### FIELD OF THE DISCLOSURE

This disclosure relates to thin film formation.

### BACKGROUND OF THE DISCLOSURE

Engineered 3D lattices at the mesoscale (e.g., 10 μm-1 mm) exhibit improved geometries for applications as lightweight mechanical metamaterials with high stiffness or bioprinted tissue scaffolds that may require precise control of pore size for engineering 3D tissue growth or regenerative tissue growth. The periodic internal structure provides opportunities for tuning the response of 3D lattices to various mechanical and thermal stimuli, as well as electric and magnetic fields. Multimaterial 3D lattices can begin to leverage this geometric tunability for new applications, such as electrochemical energy storage and shape shifting heterogeneous structures. 3D lattices can enable engineered properties that cannot be achieved with random porous materials such as foams, such as to engineer channels for efficient mass transport in redox flow batteries.

Fabricating 3D mesoscale lattices typically requires additive manufacturing methods such as stereolithography and two-photon nanolithography because standard microfabrication and micromachining methods are inherently limited in their ability to fabricate 3D geometries. This limitation means that conventional microsystems incorporating electronics (PCBs, ICs, etc.) remain stacks of planar structures due to the segmented and serial nature of the deposition, pattern, and etch paradigm. Future advances in additive manufacturing could overcome this barrier to miniaturized, multifunctional systems if electronic functionality can be integrated in 3D structures while leveraging their geometric advantages.

Electrically functional materials have been integrated with 3D printing. For example, high-resolution 3D printing by stereolithography (SLA) has been expanded from photopolymers to include percolative conductive polymer nanocomposites and polymer-derived ceramic materials. In addition, electroless and electroplating post processes have been developed for depositing micrometer-thick metal layers on 3D lattices for applications in catalysis and energy storage. Alternatively, extrusion-based 3D printing methods are available to fabricate 3D lattices comprising bulk metals, but extrusion-based 3D printing methods have lower printing resolution than SLA and two-photon lithography and require sintering at elevated temperatures. These methods for bulk material fabrication are unable to integrate nanoscale films of semiconducting and conducting materials with 3D mesostructures. Nanoscale thin films are a promising class of materials specifically for 3D-printed device applications because, unlike bulk structures, they can be exploited for their surface-driven electrostatic sensitivity to chemisorption and physisorption in various chemical and biological sensing applications.

Therefore, improved structures and techniques are needed.

### BRIEF SUMMARY OF THE DISCLOSURE

A device is disclosed in a first embodiment. The device includes a polymer structure that is a complex device in three dimensions. For example, the polymer structure can be 3D printed. A seed layer is on the polymer structure. The seed layer is an oxide, a nitride, or an oxynitride. For example, the seed layer can be at least one of Al₂O₃, SiO₂, ZrO₂, HfO₂, Y₂O₃, GeOₓ, La₂O₃, SiN, AlN, HfN, ZrN, TaN, or YN. A thin film is disposed on the seed layer.

The thin film can be a dielectric, semiconductor, or conductor. In an instance, the thin film is a metal oxide such as at least one of ZnO, SnO₂, Al₂O₃, AZO, In₂O₃, TiO₂, LiOₓ, GaOₓ, AgOₓ, NiOₓ, WOₓ, CoOₓ, InZnOₓ, InGaOₓ, InGaZnO, SnZnOₓ, SnGaOₓ, InSnGaOₓ, or InSnZnOₓ. In another instance, the thin film is at least one of In₂O₃:Sn, SnO₂:Sb, SnO₂:F, CdO:Al, or CdO. In another instance, the thin film is at least one of SiN, AlN, HfN, ZrN, TaN, or YN.

The seed layer can be configured as a barrier to subsurface diffusion into the polymer structure.

The thin film can have a thickness less than 5 nm. For example, the thin film can have a thickness from 2 nm to 500 nm.

The seed layer can have a thickness from 5 nm to 200 nm.

The polymer structure can include acrylated polyurethane, bisphenol A glycerolate (1 glycerol/phenol) diacrylate (BPAGDA), poly(ethylene glycol) diacrylate (PEGDA), polymer pentaerythritol tetraacrylate (PETA), epoxy based resins, or methacrylic acid resins.

The thin film and the seed layer can be disposed on less than an entirety of the polymer structure or an entirety of the polymer structure.

The polymer structure can be a lattice structure, can be a cantilever or beam, or can have an irregular cross-sectional geometry.

The polymer structure can have feature dimensions of less than 10 μm. For example, the feature dimensions may be from 10 μm to 3 cm.

The polymer structure has 50% to above 90% volume porosity, such as 50% to 97% volume porosity.

A method is disclosed in a second embodiment. The method includes 3D printing a polymer structure that is a complex device in three dimensions. A conformal thin film is formed on the polymer structure. The forming includes depositing a seed layer on the polymer structure. The seed layer provides a planarized adhesion layer. The seed layer is an oxide, a nitride, or an oxynitride. For example, the seed layer can be at least one of Al₂O₃, SiO₂, ZrO₂, HfO₂, Y₂O₃, GeOₓ, La₂O₃, SiN, AlN, HfN, ZrN, TaN, or YN. A thin film is deposited on the seed layer using atomic layer deposition.

The thin film can be deposited at a temperature from 30° to above 330° C. For example, the thin film is deposited at a temperature from 60° to 200° C. In another example, the thin film is deposited at a temperature from 60° to 100° C. In yet another example, the temperature is approximately 100° C.

The thin film can be a dielectric, semiconductor, or conductor. In an instance, the thin film is at least one of In₂O₃:Sn, SnO₂:Sb, SnO₂:F, CdO:Al, or CdO. The thin film can be a metal oxide. In an instance, the thin film is at least one of ZnO, SnO₂, Al₂O₃, AZO, In₂O₃, TiO₂, LiOₓ, GaOₓ, AgOₓ, NiOₓ, WOₓ, CoOₓ, InZnOₓ, InGaOₓ, InGaZnO, SnZnOₓ, SnGaOₓ, InSnGaOₓ, or InSnZnOₓ. In another instance, the thin film is at least one of SiN, AlN, HfN, ZrN, TaN, or YN.

The seed layer can be configured as a barrier to subsurface diffusion into the polymer structure.

The thin film can have a thickness less than 5 nm. For example, the thin film can have a thickness from 2 nm to 500 nm.

The seed layer can have a thickness from 5 nm to 200 nm.

The polymer structure can include acrylated polyurethane, bisphenol A glycerolate (1 glycerol/phenol) diacrylate (BPAGDA), poly(ethylene glycol) diacrylate (PEGDA), polymer pentaerythritol tetraacrylate (PETA), epoxy based resins, or methacrylic acid resins.

The thin film and the seed layer can be disposed on less than an entirety of the polymer structure or an entirety of the polymer structure.

The polymer structure can be a lattice structure, can be a cantilever or beam, or can have an irregular cross-sectional geometry.

The polymer structure can have feature dimensions of less than 10 μm. For example, the feature dimensions may be from 10 μm to 3 cm.

A device can produced using the method of the second embodiment. The device can be, for example, a gas sensor, anemometer, strain sensor, or thermistor.

### DESCRIPTION OF THE DRAWINGS

For a fuller understanding of the nature and objects of the disclosure, reference should be made to the following detailed description taken in conjunction with the accompanying drawings, in which:

FIG. 1A illustrates design and imaging of microstereolithography printed 3D mesostructure coated with conducting metal oxides of an octet lattice;

FIG. 1B illustrates design and imaging of another microstereolithography printed 3D mesostructure coated with conducting metal oxides of an octet lattice;

FIG. 1C illustrates design and imaging of another microstereolithography printed 3D mesostructure coated with conducting metal oxides of an octet lattice;

FIG. 1D illustrates design and imaging of another microstereolithography printed 3D mesostructure coated with conducting metal oxides of an octet lattice;

FIG. 1E illustrates design and imaging of a microstereolithography printed 3D mesostructure coated with conducting metal oxides of a wood pile lattice;

FIG. 1F illustrates design and imaging of a microstereolithography printed 3D mesostructure coated with conducting metal oxides of an octet lattice;

FIG. 1G illustrates design and imaging of another microstereolithography printed 3D mesostructure coated with conducting metal oxides of an octet lattice;

FIG. 1H illustrates design and imaging of another microstereolithography printed 3D mesostructure coated with conducting metal oxides of an octet lattice;

FIG. 1I illustrates an embodiment for microstereolithography printing;

FIG. 1J illustrates a layer cross-section showing 2D conducting channels coated onto 3D polymer lattice using a conformal seed layer;

FIG. 2A illustrates a scheme for conformal coating of 3D-printed mesostructures using a low-temperature (100° C.) Al₂O₃ seed layer and subsequent ALD growth of conducting and semiconducting films of SnO₂, ZnO, and AZO;

FIG. 2B illustrates a cross-section HRSEM imaging of conformal ALD ZnO films on Al₂O₃ seed layers coated onto the polymer lattices, wherein energy-dispersive spectroscopy (EDS) images (right) illustrate distinct seed layer and ZnO coating and the scale bars are 10 μm (left) and 500 nm (center);

FIG. 2C illustrates XRD spectra for metal oxide films (ZnO, Al₂O₃, SnO₂) coated onto 3D polymer lattices;

FIG. 2D illustrates XPS scans of Zn 2p peaks for 2D and 3D films;

FIG. 2E illustrates XPS scans of Sn 3d peaks for 2D and 3D films FIG. 2F illustrates XPS scans of O 1s peaks for 2D and 3D films of SnO₂ and ZnO deposited at 100° C. and 150° C.;

FIG. 3A illustrates ohmic conduction through AZO-coated conductive 3D lattices with varying ALD cycle counts;

FIG. 3B illustrates resistance versus thickness for AZO films of various thickness in 2D and 3D geometries grown at 150° C.;

FIG. 3C illustrates resistance versus thickness for SnO₂ films of various thickness compared between model and measured data with an inset showing an octet cubic structure with Au sputtered contacts for electrical measurement;

FIG. 3D illustrates resistance versus aspect ratio for AZO coated octet lattices compared between the model (predicted) and the measured data;

FIG. 3E illustrates a schematic showing octet lattices with different aspect ratios (ARs) and how these ARs were measured;

FIG. 3F illustrates resistance versus growth temperature for 3D structures with 30 nm ZnO films (square) and matching 2D ZnO films at each temperature (circle) with the polymer lattice T_{g} indicated in gray, wherein dashed lines are included as a guide;

FIG. 4A illustrates a scheme for modeling 3D conductive structures (i) by applying a lumped electrical model (ii) subsequently converted to an undirected graph (iii), for which the graph Laplacian is computed (iv) and used to predict Rcube (v);

FIG. 4B illustrates a 3D coiled lattice with gold pads for electrical measurement, indicating the predicted resistance of the overall structure based on the lattice type;

FIG. 4C illustrates predicted conductivity for 3D octet lattice networks with varying lattice constant for three different strut resistances;

FIG. 4D illustrates 3D surface area normalized by the 2D structural footprint for lattices of varying lattice constant;

FIG. 5A illustrates a comparison of chemiresistive volatile organic gas sensing with 3D octet and 2D ZnO gas sensors;

FIG. 5B illustrates a sensitivity comparison between thick and thin 3D ZnO coatings and 2D ZnO films on SiO₂;

FIG. 5C illustrates temperature-dependent resistance of 3D AZO conductor and ZnO semiconductor lattices;

FIG. 5D illustrates steady state temperature of AZO and SnO₂ coated 3D lattices as a function of applied power for joule heating;

FIG. 5E illustrates a 3D Anemometer resistive response to variable air velocity;

FIG. 5F illustrates a resistive response of 15 and 35 nm ZnO coated 3D lattices to compressive mechanical loading at varying pressure, showing an approximate 4× difference in gauge factor;

FIG. 6 shows a profilometry scan of polymer lattice fabricated using SLA showing the roughness of the surface of the structures parallel (top) and perpendicular (side) to the build plane;

FIG. 7A illustrates a scheme of the ALD process when there is no seed layer present, resulting in a zone of inhibited growth indicated with the shaded circle;

FIG. 7B is an image showing growth on SiO₂ wafer in the vicinity of the 3D lattice sample (outside the dotted line arc) as well as growth a lack of growth in the zone of inhibition around the 3D-printed part (inside the dotted line arc) resulting from growth without an Al₂O₃ seed layer;

FIG. 8 shows XRD spectra for Al₂O₃ and ZnO films grown on SiO₂ wafers by ALD;

FIG. 9 shows microscope images of 3D-printed microlattices with sputtered gold contacts on opposing sides for electrical measurements, wherein the scale bars are 1 mm;

FIG. 10 shows MATLAB graph representations of cubic volumes of octet lattices with varying lattice constants with FIG. 10A showing 333 m, FIG. 10B showing 250 m, FIG. 10C showing 200 m, and FIG. 10D showing 143 m;

FIG. 11 shows resistance change as a function of time for 11 nm and 60 nm ZnO coated 3D lattices in response to 4 lpm flow of 60° C. dry air, wherein the time constant for the first order exponential response is noted (340 ms) for the 11 nm ZnO device;

FIG. 12 shows force versus strain for two identical 3D lattices with 15 and 35 nm thick ZnO coatings;

FIG. 13 shows a 3D-printed octet lattice under compression during pressure sensing measurements with arrows indicating direction of applied force;

FIG. 14 shows renderings of octet (A), woodpile (B), and tetrakaidecahedron (C) lattice structures;

FIG. 15 is a plot of multiple independent resistance measurements of a 3D conductive lattice probed by tungsten coated needles with images illustrating how probes contact the octet lattices;

FIG. 16 is an I-V curve showing noise level conductance for a lattice structure with only an Al₂O₃ seed layer and sputtered gold electrodes;

FIG. 17 is an image showing measured octet lattice structures with sputtered gold electrodes;

FIG. 18 illustrates resistance change as a function of time for the SnO₂ cube indicating a first order time constant for the exponential response (200 ms);

FIG. 19 shows 3D anemometer resistive response to low air velocities ranging from 0.13 to 2.1 m/s;

FIG. 20 is a plot showing gauge factor extracted for multiple conductive octet lattices via mechanical compression testing at approximately 1.2% total compressive strain;

FIG. 21 is an image showing 3D-printed octet lattice under compression during pressure sensing measurements with arrows indicating direction of applied force;

FIG. 22 shows an exemplary flowchart of a process;

FIG. 23A is a schematic of a μSLA process showing example slice files, which are projections of a small fraction of the resulting part;

FIG. 23B is a μSLA printer used for printing of 3D mesostructures;

FIG. 23C is a completed print using the μSLA printer with inset highlighting the prints still attached to the print plate;

FIG. 24A is a schematic showing an exemplary ALD process;

FIG. 24B shows 3D-printed samples and control Si and SiO₂ wafer pieces on the ALD platen prior to deposition;

FIG. 24C is a system used for ALD of metal oxides in this process; and

FIG. 24D shows thickness of AZO films deposited on silicon wafers at 150° C. as a function of cycle counts that are etched and measured by stylus profilometry with error bars representing the standard deviation of ten measurements.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Fabrication of 3D mesostructured electronics by engineering nanoscale conducting films on 3D-printed polymer lattices is disclosed. This can use high-precision atomic layer deposition (ALD) of conducting and semiconducting metal oxides on ultra-smooth acrylate photopolymers or other polymers printed by high-resolution microstereolithography. Electronic transport in these 3D mesostructures is controlled by integrating an interfacial seed layer that expands the process window for uniform growth of films as thin as 5 nm. A graph theory-based approach for computing the resistance of these complex 3D structures is disclosed, which shows the elevated conductivity achieved by scaling to microscale 3D lattices. Nanoscale electronic transport can be used to demonstrate how these 3D devices facilitate multimodal sensing of chemical, thermal, and mechanical stimuli, enhancing metrics for sensitivity by 100× compared with their 2D counterparts.

While disclosed with ALD, chemical vapor deposition (CVD) can be used to accomplish the same growth mechanisms. ALD can enable high precision growth through the cyclic purging operation. CVD is typically run in a continuous flow configuration and can allow higher growth rates. Similar temperatures can be used when using CVD. Plasma enhanced CVD (PECVD) also can be used, and the growth temperatures can be lowered and the growth rates increased by introducing the plasma source.

3D lattice structures can be engineered for electronic functionality, demonstrating enhancements through dimensional scaling from the mm to the microscale. 3D-printed polymers can be transformed into versatile electronic sensors using conductive lattices fabricated by microstereolithography (μSLA) and 3D conformal ALD. μSLA can offer high-resolution through projection optics as well as larger area printing based on a step-and-repeat modality, which can be used to control the conductivity of 3D-printed lattices through structural scaling from the millimeter to the microscale. At the nanoscale, ALD allows engineering of 3D electronic transport by growing ultrathin amorphous and crystalline metal oxides (e.g., Al₂O₃, ZnO, SnO₂) at temperatures below the glass-transition temperature (T_{g}) of the photopolymer lattice. Atomic layer control of metal oxide thickness can modulate the electrostatic properties of 3D lattices, enhancing their response to thermal, mechanical, fluidic, and chemical stimuli.

These electrically conductive lattices illustrate an advantage of 3D mesostructures versus traditional 2D films for surface-driven physicochemical sensing that cannot be achieved with bulk materials. Embodiments disclosed herein can broaden the scope of additive manufacturing beyond structural components. The low-temperature processing methods can deliver these advantages through direct integration with silicon microelectronics, providing a pathway to a new class of additively manufactured wireless sensors that can leverage the properties of nanoscale materials for enhancing low-power sensing.

A resin can be photopolymerized with top down illumination through projection optics using 395 nm UV light. Design of the optics allows this process to scale down to 2 μm pixels. Larger print volumes and throughput compared with rastered two-photon polymerization can enable use with biomedical implants, robotics, etc. that demand high-resolution as well as macroscopic mechanical functionality. The high-resolution also provides an opportunity for future 3D-integration with microelectronics for systems on chip and in package.

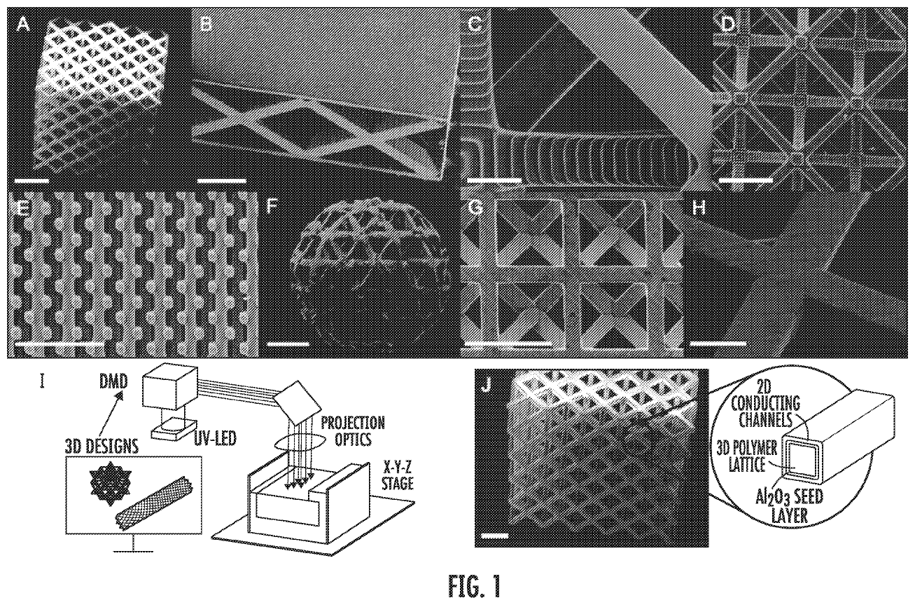

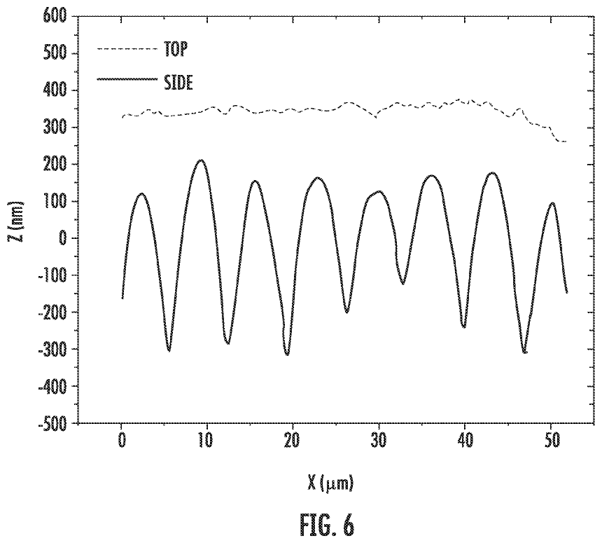

μSLA is used to generate high-resolution 3D structures in a variety of lattice geometries. FIG. 1 shows SEMs of this wide range of 3D structures coated with conductive ZnO and SnO₂ films. Scale bars are 500 μm (FIG. 1A, FIG. 1B, FIG. 1F, FIG. 1G, and FIG. 1J), 20 μm (FIG. 1C), and 100 μm (FIG. 1D, FIG. 1E, and FIG. 1H). These structures can span length scales from 10 μm features to 1 mm features including free-standing plates, octet and cubic lattices, and spherical volumes filled with lattices. The mesostructured features can be in cubic volumes. μSLA (FIG. 1I) can form high-resolution structures that can achieve varying porosities from 50% to above 90% volume porosity. 3D structures such as the octet lattice provide the mechanical stability optimal for 3D printing by microstereolithography. The octet lattice topologies used here can have high shear moduli and high surface to volume ratios due to their internal support structure. 3D printing high-resolution lattices can demand struts with sufficient mechanical strength to resist viscous forces applied by the resin leveling during printing. These structures produced by industrial scale 3D fabrication can have a surface finish sufficient to facilitate uniform 3D conformal coating (FIG. 1J). Stylus profilometry (FIG. 6) reveals that the interfaces parallel to layer formation can have an exceptionally low RMS roughness of below 31 nm, while perpendicular surfaces can inherit the natural sinusoidal roughness from layer to layer formation, resulting in RMS roughness of approximately 140 nm.

In an instance, the device includes a polymer structure; a seed layer on the polymer structure; and a thin film disposed on the seed layer. The polymer structure can be 3D printed and can include acrylated polyurethane, bisphenol A glycerolate (1 glycerol/phenol) diacrylate (BPAGDA), poly(ethylene glycol) diacrylate (PEGDA), polymer pentaerythritol tetraacrylate (PETA), epoxy based resins (e.g., DSM from Somos, Inc.), or methacrylic acid resins (e.g., from Formlabs). For example, FIG. 1J shows the polymer structure with the seed layer and FIGS. TA-1H show the polymer structure with the thin film.

The thin film and the seed layer can be disposed on an entirety or less than an entirety of the surface of the polymer structure. Selective coating on certain polymer facets or regions can be used to, for example, tune the ALD growth process so that deep internal structures are effectively left uncoated while outer structures (e.g., outer surfaces) are completely coated. This can be accomplished by reducing the time allowed for precursor introduction and purging in the growth process.

The thin film can be a dielectric, semiconductor, or conductor. The thin film can be a metal oxide, such as one or more of ZnO, SnO₂, Al₂O₃, AZO, In₂O₃, TiO₂, LiOₓ, GaOₓ, AgOₓ, NiOₓ, WOₓ, CoOₓ, or other materials. Piezoelectric or ferroelectric thin films also can be formed.

In another instance, the thin film can include a transparent conductor that includes one or more of In₂O₃:Sn, SnO₂:Sb, SnO₂:F, CdO:Al, or CdO. In yet another instance, the thin film can include alloyed oxides such as InZnOₓ, InGaOₓ, InGaZnO, SnZnOₓ, SnGaOₓ, InSnGaOₓ, or InSnZnOₓ.

The seed layer can be at least one of Al₂O₃, SiO₂, ZrO₂, HfO₂, Y₂O₃, GeOₓ, La₂O₃, or other materials. The seed layer can be configured as a barrier to subsurface diffusion into the polymer structure.

While disclosed with oxides, the seed layer also can include a nitride. Nitrides can sufficiently passivate the surface of the 3D printed polymer structures. Examples of these materials can include SiN, AlN, HfN, ZrN, TaN, or YN. These materials can be grown by ALD processes. Nitrides can be used as a barrier material, so nitrides may also present advantages for passivating the polymer surface in potential applications to parts/fixtures for space applications or vacuum equipment. A mixture of an oxide and a nitride is possible.

The seed layer also can be an oxynitride. The oxynitride can include silicon, aluminum, hafnium, zirconium, tantalum, or yttrium.

It is expected that oxides, nitrides, and oxynitrides can serve as a barrier to subsurface diffusion into the polymer structure. Oxides, nitrides, and oxynitrides may have different passivation properties, but this may not affect their benefits as a barrier. The thin film and the seed layer can be the same material or different materials. The thin film and the seed layer can each be a single material or a mixture of materials.

If the seed layer includes or is composed of a nitride, then the thin film can be SiN, AlN, HfN, ZrN, TaN, or YN. These materials can act as seed layers, but can be deposited in multilayer stacks as the subsequent thin film.

The thin film can have a thickness from 2 nm to 500 nm, including all values to the 0.1 nm and ranges in between. In an instance, the thin film can have a thickness less than 5 nm (e.g., from 2 nm to 5 nm), from 5 nm to 160 nm, or from 7 nm to 70 nm. For example, the thin film can have a thickness of approximately 2 nm for ZnO or SnOₓ. In another example, the thin film can have a thickness from 2 nm to 40 nm that produces semiconductor behavior that induces surface depletion effects. In yet another example, the thin film can have a thickness of 40 nm to 500 nm for conductive electrodes. Other dimensions or ranges are possible and are disclosed herein. The thickness of the thin film can be applied with a uniformity to provide continuous films on the relevant internal geometries (e.g., all internal geometries). Uniformity can be affected by surface properties.

A thin film with thinner dimensions is possible. Sub 1 nm semiconducting layers can be formed using ALD. For example, In₂O₃ is one example for which even such ultrathin films (0.7 nm) can be functional.

Thin films with thicker dimensions also is possible. The ALD process can be modified to speed up the growth rate by removal of temporal separation in the pulses of the precursor. For example, films up to 10 μm may be feasible. The deposition temperature can be kept close to room temperature (e.g., <100° C.) to minimize stress.

In an example, the thin film thickness is affected by the Debye length of the semiconductors. Layers that are designed to be sensitive to chemical or thermal stimuli can be designed in the range of 10-100 nm to have amplified sensitivity. Physisorption and chemisorption may both be more influential (electronically) when the film is thin enough to have electrostatic coupling across its thickness.

The seed layer can have a thickness from 5 nm to 200 nm. In an instance, the seed layer can have a thickness from 10 nm to 20 nm, 20 nm to 80 nm, or 20 nm to 200 nm. Other dimensions or ranges are possible and are disclosed herein. For example, thinner seed layers (e.g., 2 nm) can be used if the seed layer is applied in a uniform manner. While these thinner seed layers may be feasible, a thicker seed layer can improve passivation of the surface of the polymer.

The thin film can be deposited at a temperature from 300 to above 330° C. For example, the thin film can be deposited at a temperature from 600 to 225° C. The temperature can be from 600 to 200° C., from 600 to 100° C., or approximately 100° C.

The polymer structure can be a complex device in three dimensions. For example, the polymer structure can be a lattice structure or can be a cantilever or beam. The polymer structure can have an irregular cross-sectional geometry. Feature sizes on the polymer structure can be less than 10 μm or can be from 10 μm to 3 cm. In an instance, the polymer structure has 50% to above 90% volume porosity (e.g., up to 97% volume porosity).

ALD is a high-precision method for growth of nanoscale thin films of functional metal oxide materials at low temperatures. ALD can allow uniform, conformal growth of various dielectrics, semiconductors, and conductors useful in microelectronics as well as a variety of other applications in energy and sensing. ALD can be used to coat microscale 3D-printed polymer lattices with conducting (SnO₂, ZnO:Al) and semiconducting (ZnO) metal oxides films. The embodiments disclosed herein can be extended to a broad range of functional metal oxide thin films as well as a range of different 3D-printed polymer lattices.

ALD growth can be inhibited by polymers such as polymethylmethacrylate (PMMA) and poly (vinyl pyrrolidone) (PVP) depending on growth conditions and precursor chemistry. The ALD process can induce sub-surface growth in certain polymer substrates (e.g., polyethylene) which can effectively inhibit the formation of functional thin films such as transparent conductors. Vapor phase infiltration of ALD precursors such as trimethylaluminum (TMA) into various polymers can be used for fabricating hybrid organic/inorganic structures. Mechanistic studies of ALD growth on polymers have differentiated lower growth-temperature regimes in which overcoats are formed and higher-temperature regimes in which subsurface diffusion leads to particle growth and roughening.

Low-temperature deposition of ceramic seed layers (Al₂O₃) at 100° C. leads to the ability to coat transparent conductive films composed of ZnO, AZO, and SnO₂ on the 3D structures fabricated by microstereolithography. Without an Al₂O₃ seed layer, growth of the conductive film on the polymer is inhibited. While not intended to be limiting, failure modes can occur when it is inhibited. In an instance, the ALD precursor molecules penetrate into the polymer and form a nanocomposite rather than an overcoat film. This can occur when depositing films at high temperatures (e.g., above polymer's T_{g}). In another instance, the polymer surface may not be as favorable for ALD precursors to adsorb to. The Al₂O₃ seed layer can address these problems by acting as a barrier to the diffusion of the subsequent ALD precursors into the bulk of the polymer rather than staying on the surface. The Al₂O₃ seed layer also can provide a coating with an optimal surface energy for uniform coating and growth by ALD.

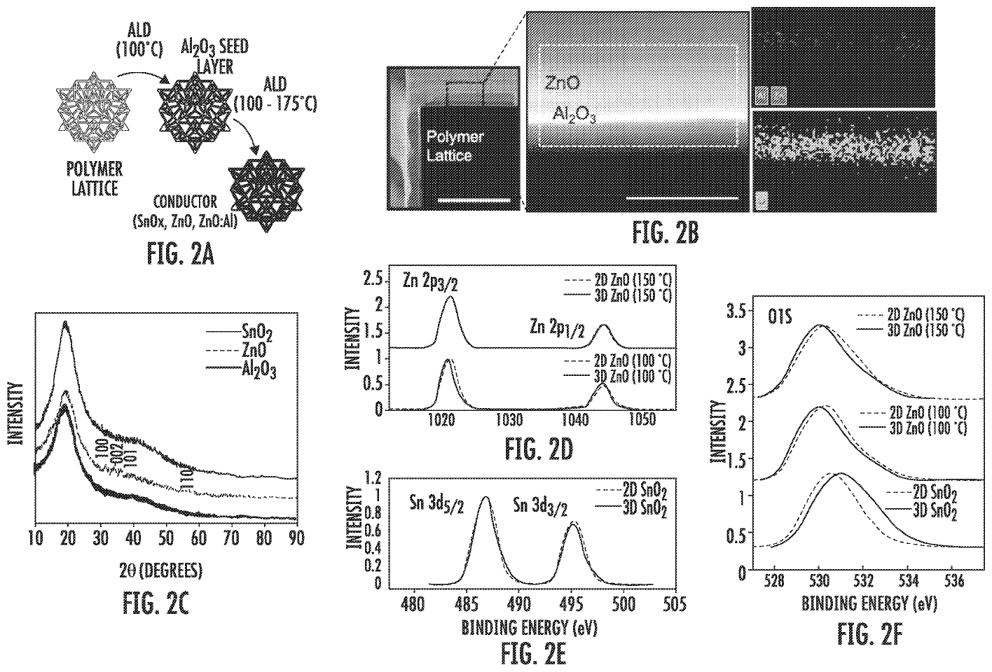

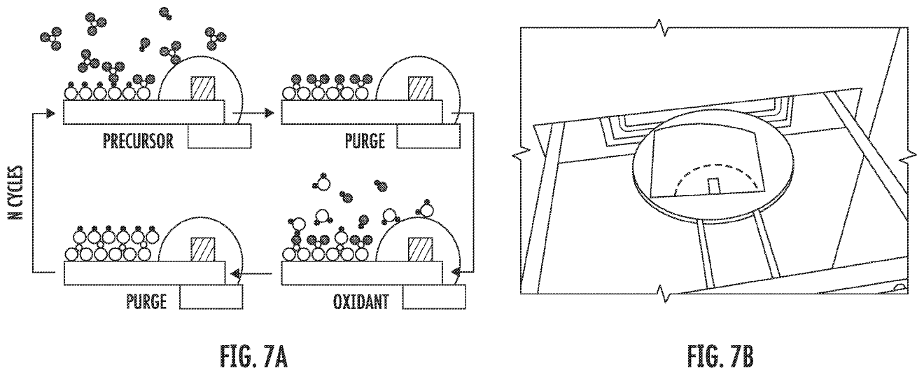

There can be a zone of inhibited growth surrounding the part in the ALD chamber. FIGS. 7A-7B show inhibited growth of conductive films on 3D mesostructures observed when depositing on 3D lattices without an Al₂O₃ seed layer. Various polymer materials were tested with this method of surface passivation and confirmed to conduct, indicating that this process is applicable to a wide range of material chemistries. The ALD growth process on 3D-printed polymers may depend on growth temperature. FIG. 2 illustrates a demonstration of metal oxide growth on 3D-printed mesostructures. The low temperature (approximately 100° C.) ALD process forms a 10-20 nm seed layer, which can passivate the 3D surface and lead to a high-precision ALD coating regime (FIG. 2A) for subsequent deposition of distinct functional conductive and semiconducting layers, as shown in the cross-sectional SEM images and EDS maps in FIG. 2B. With this low-temperature seed layer, growth of continuous conductive films was achieved across a wide range of temperatures up to and slightly above the glass-transition (T_{g}) of the acrylate polymer lattices used herein (e.g., 172° C.). Additionally, conductive coatings were grown on 3D-printed polymers from multiple other vendors, illustrating the generality of this approach.

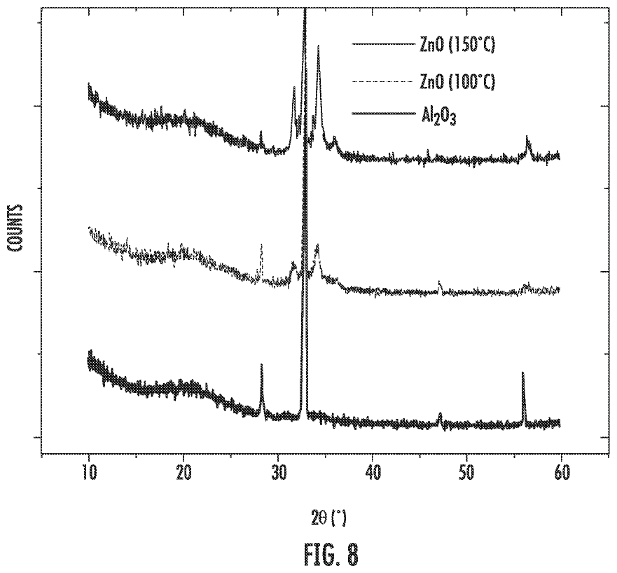

XRD studies of the coated 3D structures (FIG. 2C) show the amorphous phase for the Al₂O₃ seed layers and the SnO₂ conductor films. The 3D ZnO films, however, show (100), (002), and (101) peaks consistent with the nanocrystalline hexagonal wurtzite phase that match the peak locations for identical planar ZnO growths on SiO₂ (FIG. 8). The XPS studies shown in FIGS. 2D-2F illustrate the chemical composition of ALD grown ZnO and SnO₂ films deposited on the polymer lattices in comparison with films deposited on SiO₂ wafers. The metal peaks for Zn (2p) and Sn (3d) exhibit strong correspondence between the 2D and 3D samples. This is true across the range of growth temperatures, as shown for ZnO deposited at 100° C. and 150° C. The comparison of the 0 (1s) peaks shown in FIG. 2F indicates the ability for 3D ALD growth to produce films with similar stoichiometry (ZnO, SnO₂) on polymeric lattices as compared with traditional 2D surface growth. This can help achieve high conductivity in these metal oxide materials.

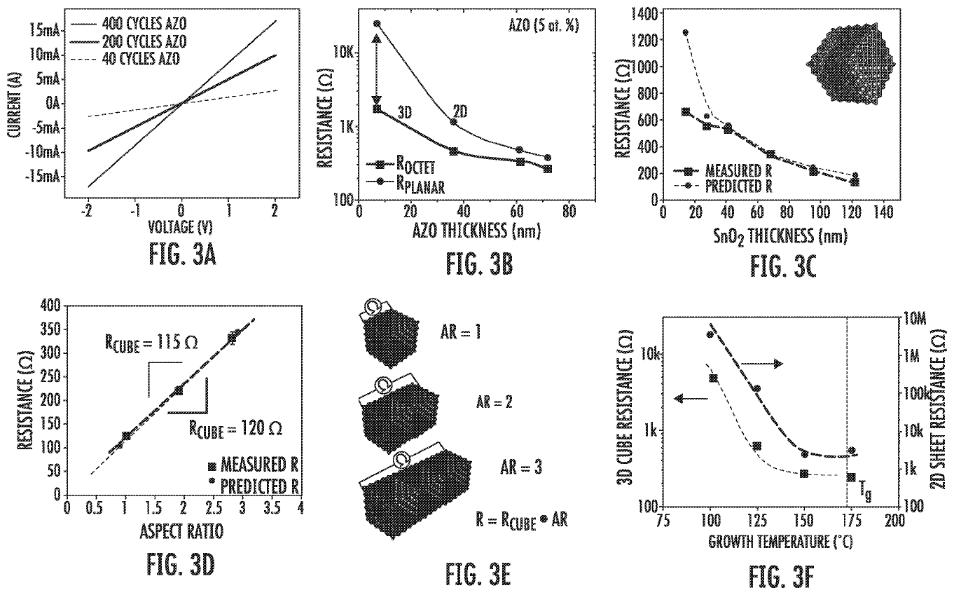

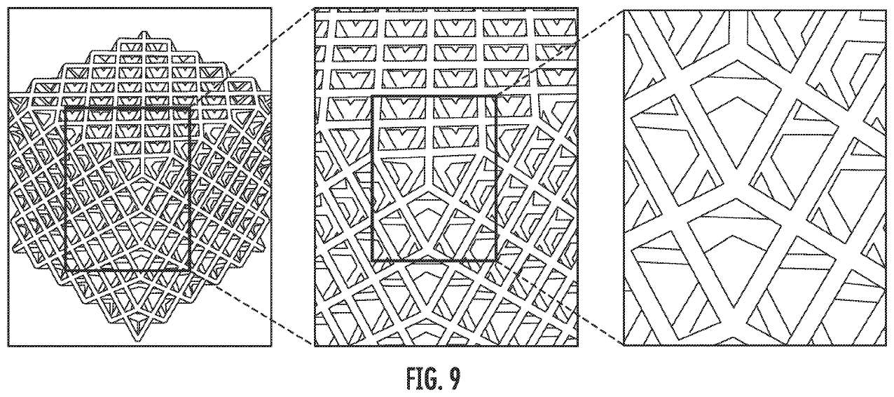

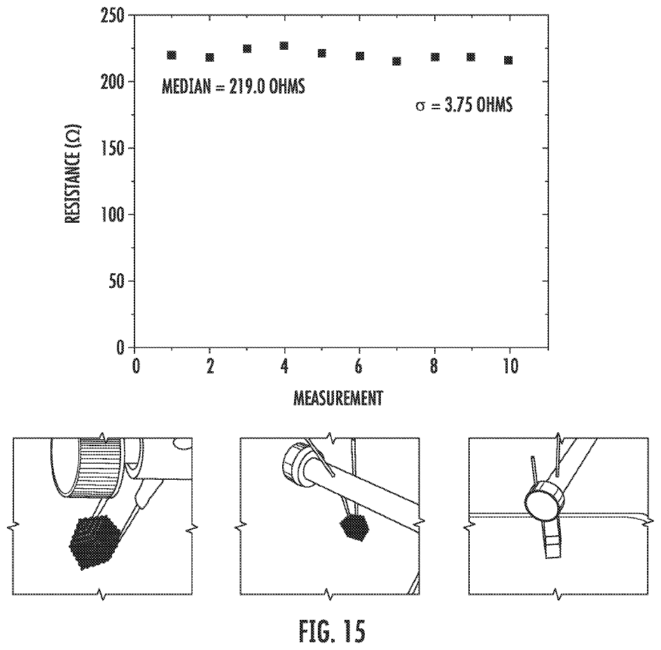

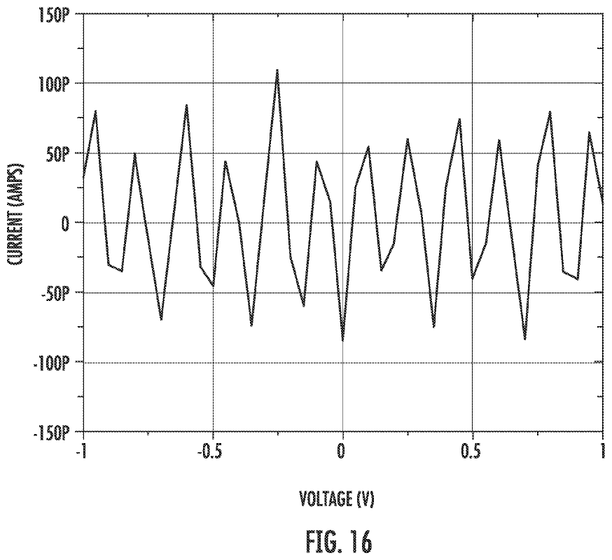

The 3D conductive lattices coated with ZnO, ZnO:Al (AZO), and SnO₂ were measured electrically by depositing conformal Au contacts on opposing faces by sputter deposition (FIG. 9) and probing with a semiconductor microprobe station (FIG. 15). Without deposition of the conducting oxide (ZnO, SnO₂, or AZO), the 3D lattices are nonconductive (FIG. 16). After coating, the 3D lattices demonstrate improved conductivity even for ultrathin films formed by only 40 cycles of ALD deposition (i.e., approximately 7 nm thickness). FIG. 3 illustrates demonstrated electrical properties of metal oxide coated 3D-printed mesostructures. FIG. 3A shows the I-V response of the lattices, illustrating the Ohmic conduction across an AZO coated 3D structure with various ALD growth cycle counts from 40 to 400 (approximately 7 to 70 nm thickness). The effective resistance of the 3D structures can scale strongly with the thickness. FIG. 3B compares the resistance per cube of AZO coated 3D lattices with the measured 2D sheet resistance, showing the enhancement in conductance for the 3D networks that can fold nanoscale films into their internal geometries with higher total surface area, offering parallel paths to current conduction. Similarly, the resistance of 3D lattices coated in SnO₂ can be reduced via deposition of thicker films, reaching the predicted resistances of below 200Ω (FIG. 3C). Controlling the growth temperature allows deposition of more conductive 3D networks of ZnO, AZO, and SnO₂, as illustrated in FIG. 3D, for films grown at temperatures between 100° C. and 175° C. The ALD process can produce highly conductive 3D networks from ultrathin films (30 nm ZnO), even when operating slightly above the glass transition temperature of the polymer lattice (Tg=172° C.). The ALD methods disclosed herein can deposit high quality films in 3D geometries in this temperature range from 100° to 175° C., which may facilitate the application of this method to a variety of new electronic material systems.

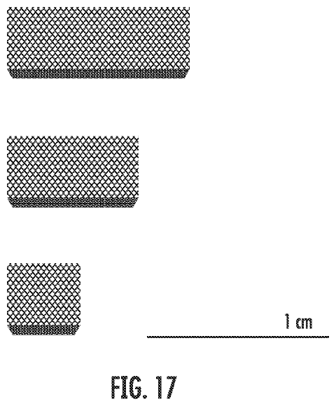

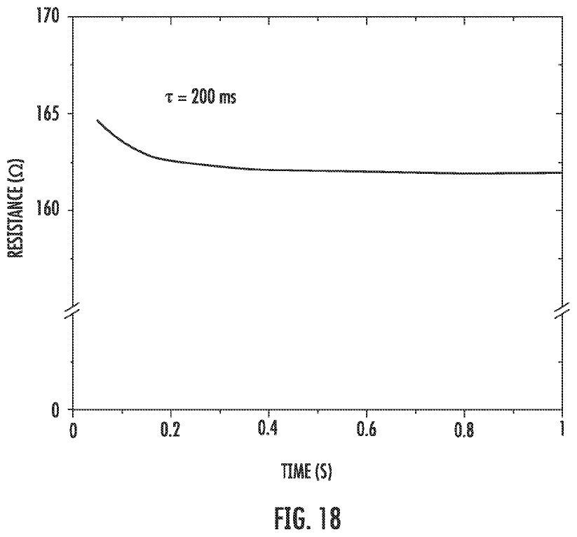

FIG. 3D shows the predicted and measured resistances of AZO-coated octet lattices with varied aspect ratio. FIG. 3E emphasizes the size difference between the lattices and illustrates how they were contacted during measurement (see also FIG. 17). Controlling the growth temperature can allow deposition of more conductive 3D networks of ZnO, AZO, and SnO₂, as illustrated in FIG. 3F, for films grown at temperatures between 100° C. and 175° C. ZnO and SnO₂ films grown in this temperature range achieve resistivities of 8.5×10⁻³ and 4×10⁻² Ω-cm, respectively, which are typical of these ALD-processed materials.

The temperature used in the embodiments disclosed herein may be high enough to have sufficient vapor pressure for the ALD precursor gas. The temperature can be lower (30° C.) for some materials (e.g., Al₂O₃), while most other ALD materials may be at higher temperatures (>60° C.). Low temperature growth may use plasma-enhanced growth. If the growth temperature is too high, the glass transition temperature of the polymer may be exceeded and there is a risk of damaging the device. Above the heat deflection temperature (i.e., near the T_{g}), the polymer can begin to deform and the 3D structure may be distorted. The high growth temperatures also can lead to subsurface growth of the ALD film inside the polymer rather than on the surface. The ALD growth inside the polymer may not be a continuous film.

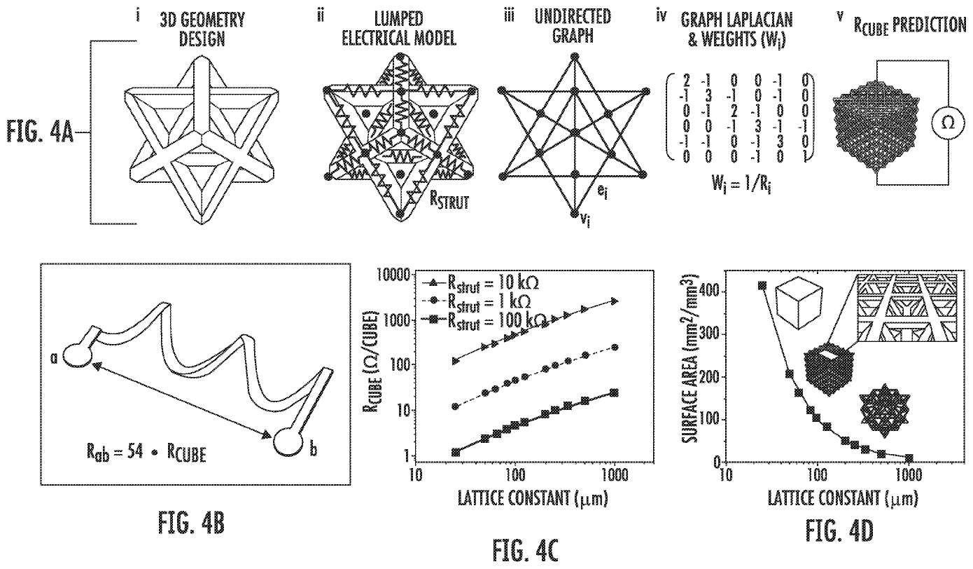

FIG. 4 illustrates a graph theory model and predictions of 3D lattice conductivity. The 3D conductive lattices disclosed herein can precisely control the porosity, surface area, and electrical conductivity in 3D. These lattices can be architected in nearly any conceivable 3D structure, with a precisely designed conductance. An approach adapted from graph theory and network science can be used to determine the conductance of arbitrary 3D structures utilizing a lumped element representation implemented as an undirected graph with edge weights corresponding to each strut's conductance (Gᵢ=1/Rₛₜᵣᵤₜ) as shown in FIG. 4A. The strut resistance (Rₛₜᵣᵤₜ) is then calculated based on the geometry of the square profile beams (length L, width D) as well as the thickness (t) and resistivity (ρ) of the metal oxide coatings using Eq. 1.

Rₛₜᵣᵤₜ=Lρ/4Dt

The method then includes generating the adjacency matrix and computing a weighted, pseudo-inverse Laplacian, Qt. Effective resistance between any two points in an arbitrary 3D structure can be calculated as follows using Eq. 2.

$${R}_{a b} = {Q}^{†} ( a , a ) - 2 {Q}^{†} ( a , b ) + {Q}^{†} ( b , b )$$

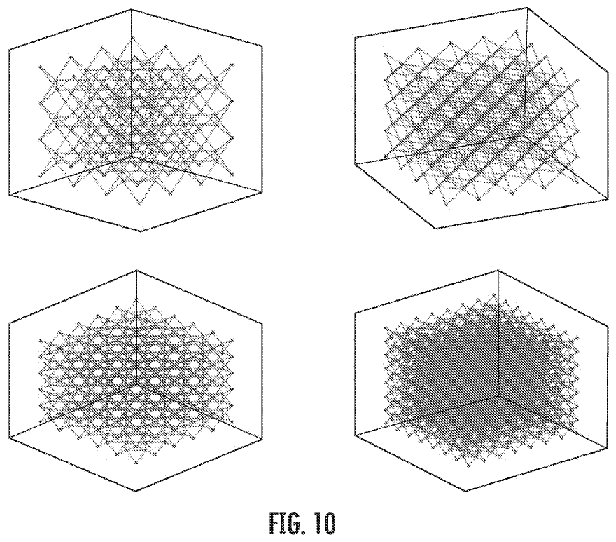

The weighted Laplacian method can be applied to model a range of finite octet lattices filling a 1 mm³ cubic volume with varied lattice constants (FIG. 10). This can enable determination of a volumetric resistance quantity (R_{cube}), which can be compared against experimental measurements of oxide-coated 3D-printed octet lattices. R_{cube} has dimensions Ω/cube, forming a 3D analog to a 2D sheet resistance (Ω/square) for 3D microarchitected materials. The volumetric resistance of the lattice structures, R_{cube}, can be controlled by scaling the lattice constant or by adjusting the conductance of the individual struts (e.g., tunable via the ALD cycle count). To model complex 3D structures with lattice infill, such as the corkscrew structure shown in FIG. 4B, the computed base unit resistance, R_{cube}, can be scaled by multiplying by an appropriate 3D aspect ratio to determine the resistance from point a to point b (R_{ab}). FIG. 4C displays the computed resistance per cubic volume, R_{cube}, for 3D octet structures with varying lattice constants from 25 to 1,000 μm. Finer 3D lattices naturally offer additional parallel paths for current conduction, providing a lower volumetric resistance, R_{cube}, for a given 1 mm³ volume. The implication of this scaling is that higher-resolution 3D printing can geometrically enhance 3D electronic conduction. For example, structures with 10 μm features at the limits of industrial μSLA would offer 20× higher conductance for a given coating compared with 200 μm printed features as may be created by lower-resolution 3D-printing methods such as fused deposition modeling (FDM). The more geometrically complex face-centered-cubic (fcc) lattices printed by SLA have been theoretically predicted to have approximately twice the relative electrical conductivity compared with diamond or simple cubic lattices for a given unit cell size and element resistance.

This method can be applied to construct a large variety of octet lattices filling a 1 mm³ cubic volume with varied lattice constants (FIG. 10) to compute a volumetric resistance quantity labelled as R_{cube}. R_{cube} has dimensions Ω/cube, forming a 3D analog to a 2D sheet resistance for 3D microarchitected materials. The volumetric resistance of the lattice structures, R_{cube}, can be controlled by scaling the lattice constant or by adjusting the conductance of the individual struts (tunable via the conformal growth process). To model larger lattice structures or lattice structures with different geometries, a system of octet lattices, or multiple R_{cube} values, can be created in series or parallel and the calculated volumetric resistance values can be added appropriately to determine the resistance across a structure, R_{ab}, as shown in FIG. 4B. FIG. 4C displays the computed volumetric resistance, R_{cube}, for 3D octet structures with varying lattice constants from 25 μm to 1000 μm. Finer 3D lattices can offer additional parallel paths for current conduction, providing a lower volumetric resistance, R_{cube}, for a 1 mm³ volume. The implication of this scaling is that higher-resolution SLA printing can be used to provide geometrically enhanced 3D conductive structures. For example, structures with 10 μm features at the limits of industrial μSLA can offer 20× higher conductivity compared with 200 μm printed features created by lower resolution methods such as FDM).

The geometrical advantages of 3D lattices derive from their enhanced surface area compared with planar films. As shown in FIG. 4D, conductive 3D lattices can reach surface areas orders of magnitude higher than planar films, providing enhancement of 400× over 2D films in the case of the octet lattices printed in these examples. This surface area enhancement can scale inversely with the lattice constant for high-resolution, dense 3D lattices. The surface area of the 3D porous structures may be used to determine performance in applications to electrochemical energy storage, electrocatalysis, and 3D-printed fuel cells. Likewise, surface area can be a factor for determining sensitivity of metal oxide nanomaterials to various chemical analytes, such as liquids and gases.

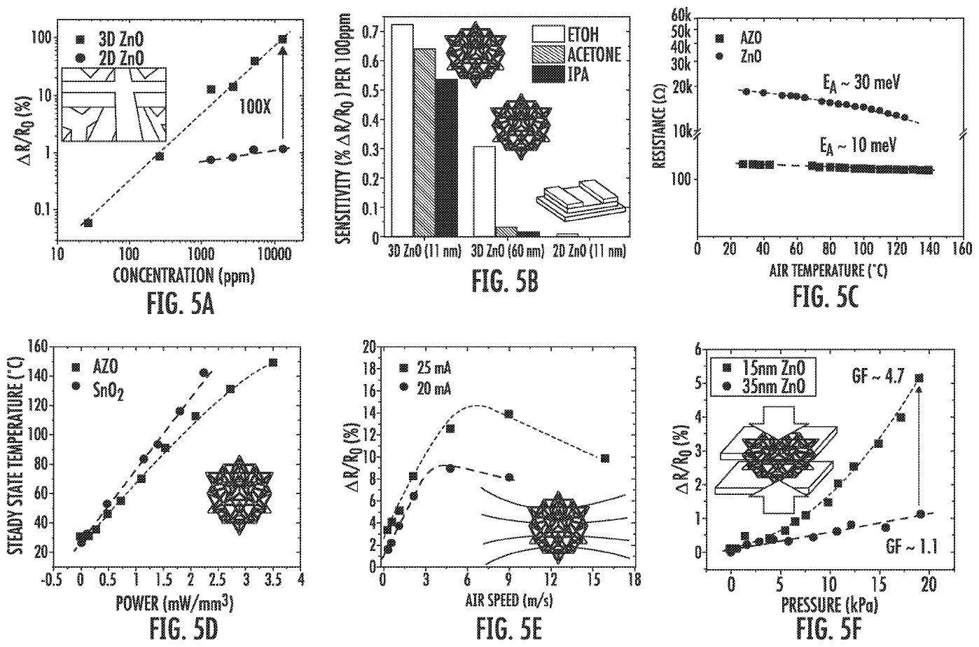

FIG. 5 shows enhanced chemical, thermal, and mechanical sensing capabilities of 3D lattices. The conductive lattices were applied as multimodal chemical, thermal, and mechanical sensors to explore the 3D enhancements to their sensing functionality. The 3D lattices composed of ultrathin ZnO were implemented as room temperature, low-power gas sensors, showing a significant response to volatile organic compounds (VOCs) including ethanol, isopropyl alcohol, and acetone in the range of 1-10,000 ppm without the high power consumption of embedded heaters used in state-of-the-art commercial gas sensors. The 3D geometries can provide an enhancement in the relative change in resistance at a given gas concentration with respect to 2D films deposited by the same ALD process. For example, 3D lattices with ultrathin 11 nm ZnO coatings show a 100× enhancement in sensitivity relative to identical 2D films for ethanol sensing at the ppm level (FIG. 5A). This trend holds for multiple gaseous analytes and across a large dynamic range (1000×) of gas concentrations, illustrating the power of 3D geometrical design to enhance sensing functionality of metal oxides (FIG. 5B). Unlike various other 2D film-based gas sensors, the 3D geometries shown here achieve high surface area while allowing for operation as flow-through sensors can avoid additional bulky packaging. The 3D printing process here also can minimize the necessary footprint of the sensors, eliminating the need for larger arrays of interdigitated electrodes patterned by photolithography.

This demonstrated ability to grow ultrathin semiconducting and conducting films with controlled thickness at the nm-scale may be important for tuning the electrostatics towards sensing applications. Semiconductor films, including inorganic oxides utilized for liquid and gaseous sensing, have an electrostatic surface sensitivity determined by their thickness relative to the Debye Length (L_{D}), which is shown below in Eq. 3.

$${L}_{D} = \sqrt{\frac{ε {k}_{B} T}{{q}^{2} n}}$$

In Eq. 3, ε is permittivity, k_{B} is the Boltzman constant, q is the charge on an electron, n is the free carrier concentration, and T is temperature.

For example, the VOC sensing capabilities of 3D lattice structures with thin (11 nm) and thick (60 nm) ZnO were compared, as shown in FIG. 5B illustrating the enhanced resistive response of the ZnO 3D structures. Debye length estimates based on carrier concentration for the more resistive ultrathin 11 nm (L_{D}˜25 nm) and 60 nm (L_{D}˜2 nm) ZnO can explain the enhanced response at low gas concentrations. Thinner semiconductor films for which tₛ<L_{D} typically have surface-dominated electrostatic interactions with physisorbed gas molecules. In the embodiments disclosed herein, the Al₂O₃ seed layer can facilitate uniform ultrathin growth at the nm-scale, which can achieve room-temperature chemical sensitivity of metal oxides for ultra-low-power Internet of Things (IoT) applications.

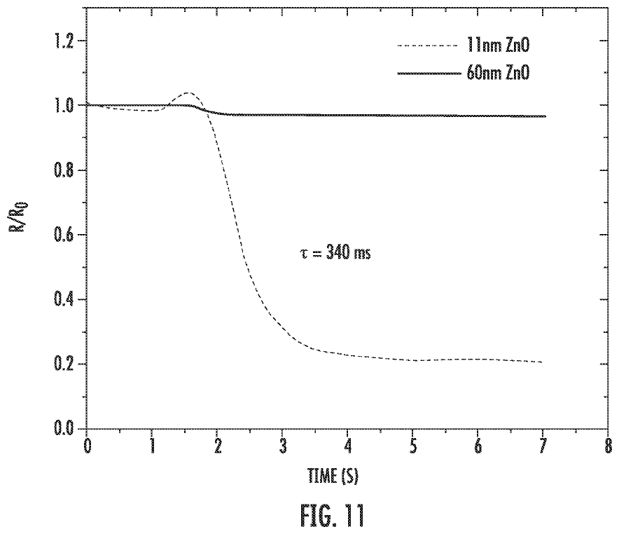

Similarly, highly conductive films of AZO and SnO₂ at thicknesses of approximately 100 nm can facilitate multimodal, thermophysical sensing. FIG. 5C illustrates the variation of resistance of 3D ZnO and AZO coated octet lattices with temperature, illustrating the enhanced response of semiconducting ZnO functioning as a thermistor. The low thermal mass of these porous 3D lattice structures has considerable advantages for enhancing its response to rapid changes in air temperature. As shown in FIG. 11, the 3D structures sense air temperature changes with a first order time constant of approximately 340 ms, comparable to state-of-the-art fine-gauge thermocouple elements, but offering a variety of opportunities for structural 3D integration.

Thicker films of degenerate SnO₂ and AZO with resistance approaching 100Ω, however, can offer the ability to induce self-heating, as shown in FIG. 5D. Using infrared thermometry, the lattice structures were observed to rapidly reach temperatures from 40° C. to 140° C. with less than 3.0 mW/mm³ of applied power. This internal heating of these structures (e.g., approximately 200 ms) is useful for various sensing applications that may require higher temperatures to operate effectively. The self-heating function of these low thermal mass, free-standing 3D structures also can facilitate their use as thermal anemometer flow sensors by monitoring the convective cooling of the lattice with air flowing through it, as demonstrated in FIG. 5E. Self-heated octet structures can allow sensing across approximately a 100× range of air velocities, extended through higher operating currents.

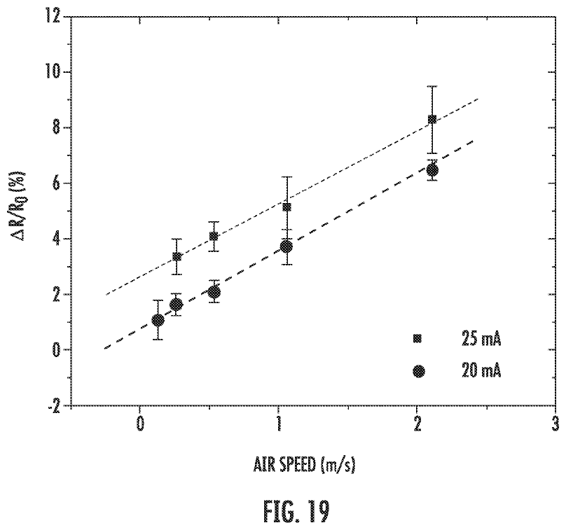

Self-heated octet structures allow anemometry across an approximately 40× dynamic range of air velocities from 0.13 to 5 m/s. These devices achieve a sensitivity of approximately 1-2 mV/(m/s)/mW in the linear regime (FIG. 19), which is comparable to the sensitivity reported for microelectromechanical systems (MEMS) hot-wire anemometers. The disclosed millimeter-scale 3D-printed anemometer can achieve sensitivity without requiring photolithography and complex etching steps and that it is more compact than commercial products.

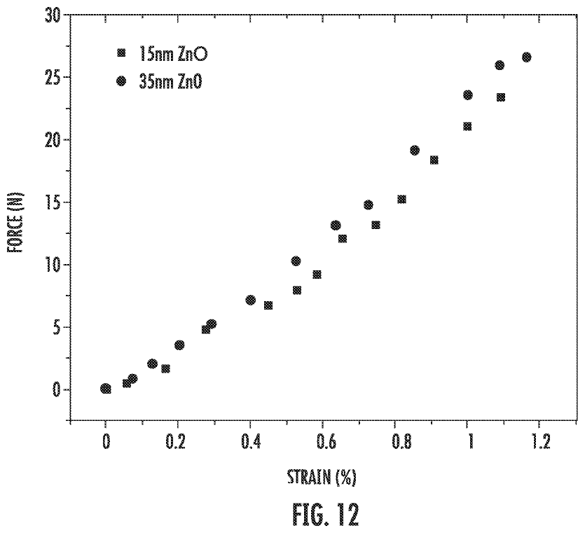

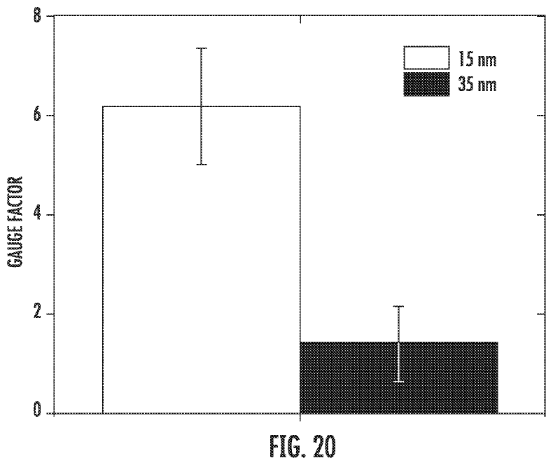

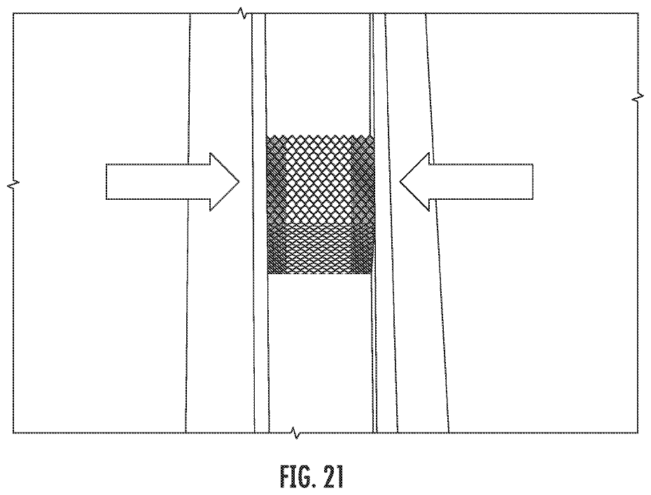

These ceramic-coated, conductive 3D structures can serve as custom pressure sensors. FIG. 5F illustrates resistance changes in response to applied pressure for octet lattices with different thickness of ZnO coatings (15 and 35 nm). FIG. 12 shows a linear relationship between strain and force. This shows an effective modulus (e.g., 200 MPa) is in effect, dictated by the struts parameters such as radius, height, arrangement, etc. The resistance change shown in the FIG. 5F is more pronounced for the lattice with thinner ZnO within a pressure and strain range up to 20 kPa and 1.2% uniaxial strain (FIG. 12). The 4× improved sensitivity in the thinner coating also reflects commensurately in the Gauge Factor (GF), 4.7 and 1.1 for 15 nm and 45 nm ZnO coating, respectively. The GF reached approximately 6.2±1.2 and 1.4±0.7 for 15 and 35 nm thick films, respectively, at a value of 1.3% compressive strain (FIG. 20). These GFs match well with the piezoresistive properties of ZnO. The increment in GF can be attributed to the thinner coating being more semiconducting and less metallic compared to the thicker ZnO. This demonstrates tunability in mechanical response that can result from coating nanoscale semiconductor films. The 3D conformal coating can provides a basis for mechanical sensing elements in various custom geometries for micromachines and microrobotics. Tunability in mechanical response that stems directly from the ability of this strategy to coat nanoscale semiconductor films is possible. The effective modulus of the 3D-printed polymer structures can be modified by changing the lattice geometry (e.g., beam thickness), which can allow tuning of the force sensing range without modifying the sensing material. The 3D ALD coating can provide a basis for the future design of custom mechanical sensing elements in various custom geometries for microrobotics requiring sensitivity to a high dynamic range of forces.

Embodiments disclosed herein can fabricate conductive 3D mesostructures by transforming 3D-printed polymers into devices through the deposition of ultrathin conductive oxides. Multimaterial ALD growth of conductive, insulating, and semiconducting films can be combined with high-resolution μSLA to produce 3D lattice structures with microscale features (e.g., down to 10 μm) that demonstrate geometric advantages for electronic transport. A graph theory-based approach can model 3D conductive networks and explore their enhancement to electrical properties as well as potential for multimodal sensing with engineered high surface area 3D structures. Capabilities of the disclosed 3D electronic integration bridge nanoscale electronic material design with micro and mesoscale 3D design, which can allow a multifunctionality applicable to fluid, thermal, chemical, and mechanical sensing. By pairing the electronic material and structural designs, mesoscale structures can be engineered with nanoscale coatings to improve sensing capabilities 100× as compared to 2D counterpart devices for room temperature, low-power gas sensing. Ultrathin films provide higher surface sensitivity allowing for devices intentionally designed as conductors or semiconductors which, when combined with the 3D-printed structures, make it possible to design devices for specific to a certain application. This can be used in applications in mesoscale devices, such as implanted biomedical sensors to rapid custom fabrication of 3D integrated microelectromechanical systems.

The following examples are provided for illustrative purposes and are not intended to be limiting.

### Example 1

Additively manufactured (AM) three-dimensional (3D) mesostructures exhibit geometrically optimal mechanical, thermal, and optical properties that could drive future microrobotics, energy harvesting, and biosensing technologies at the micrometer to millimeter scale. Transforming AM mesostructures into 3D electronics by growing nanoscale conducting films on 3D-printed polymers is disclosed. This technique utilizes precision ALD of conducting metal oxides on ultrasmooth photopolymer lattices printed by high-resolution microstereo lithography. Control of 3D electronic transport is demonstrated by tuning conformal growth of ultrathin amorphous and crystalline conducting metal oxides. 3D-enhanced multimodal sensing of chemical, thermal, and mechanical stimuli is demonstrated, geometrically boosting sensitivity by 100× over 2D films and enabling a new class of low-power, 3D-printable sensors.

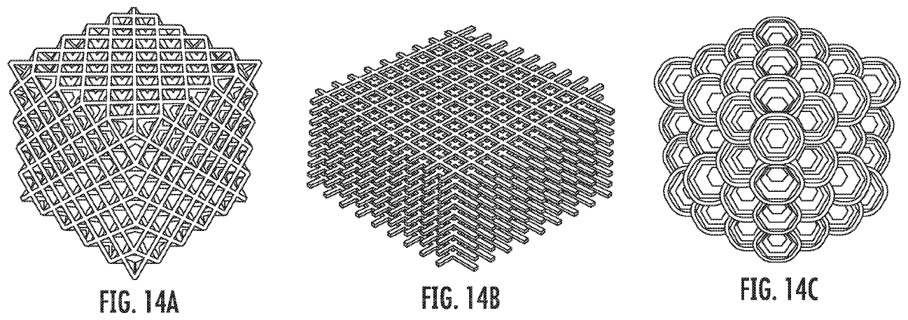

μSLA was used to generate high-resolution 3D structures in a variety of lattice geometries. The μSLA system exposes a photopolymer resin with top-down illumination through projection optics using a 405 nm ultraviolet light-emitting diode. The optics can be configured to allow this process to scale down to 2 μm pixels. FIG. 1 shows scanning electron microscope (SEM) images of this wide range of 3D structures coated with conductive ZnO and SnO₂ films. These structures span length scales from 10 μm features to millimeter-scale features, including free-standing plates, octet, cubic, and tetrakaidecahedron lattices (FIG. 14) and spherical volumes filled with octet lattice. This shows the power of μSLA (FIG. 1I) to form high-resolution mesostructures that can achieve varying porosities from 50% to above 90% volume porosity without suffering from the mechanical fragility that limits bulk porous materials such as aerogels. Three-dimensional structures such as the octet lattice provide the mechanical stability optimal for resisting mechanical stresses during 3D printing by μSLA. The octet lattice topologies used here have high shear moduli and high surface area-to-volume ratios due to their internal support structure. The mechanics of these lattices is can demand struts with sufficient mechanical strength to resist viscous forces applied by the resin leveling during printing.

These structures produced by industrial 3D fabrication can have an ultrasmooth surface finish sufficient to facilitate uniform 3D conformal coating (FIG. 1J) of electronic films. Stylus profilometry (FIG. 6) reveals that the interfaces parallel to layer formation exhibit a low root-mean-square (RMS) roughness of below 31 nm, while surfaces perpendicular to the build plane inherit the sinusoidal waviness induced by the layer-by-layer SLA process, resulting in an RMS roughness of approximately 140 nm. In comparison, other 3D printing methods, such as fused deposition modeling (FDM) and binder jet printing, produce structures with a surface roughness of 2-200 μm, making it harder to deposit ultrathin films onto the materials. FIG. 1C illustrates a magnified view of the smooth surfaces of faces parallel to the build plane of the μSLA process, while FIG. 1H shows micrometer-scale ridges produced on the lateral faces of parts. This is typical for SLA, but could eventually be alleviated by advanced gray-scale lithography methods.

Given the ultrasmooth surface of these μSLA parts, ALD, a high-precision method for growth of nanoscale thin films, can be used to deposit functional metal oxide materials at low temperatures onto the 3D structures. ALD allows uniform, conformal growth of various dielectrics, semiconductors, and conductors useful in microelectronics as well as a variety of other applications in energy and sensing. ALD can coat microscale 3D-printed polymer lattices with conducting (SnO₂, ZnO:Al) and semiconducting (ZnO) metal oxide films. This technique can be used for a broad range of functional metal oxide thin films as well as a range of 3D-printed polymer lattices.

A low-temperature-deposited (100° C.) seed layer of Al₂O₃ is used, which then leads to the ability to uniformly coat transparent conductive films composed of ZnO, ZnO:Al (AZO), and SnO₂ on 3D structures fabricated by μSLA. Without an Al₂O₃ seed layer, growth of the conductive films on the 3D-printed polymers is inhibited. There may be a zone of inhibited growth surrounding the part in the ALD chamber (FIG. 7), which can be eliminated via deposition of the seed layer. The ALD growth process on 3D-printed polymers depends on growth temperature. The low temperature (approximately 100° C.) ALD process forms a 10-20 nm seed layer passivating the 3D surface and leading to a high-precision ALD coating regime (FIG. 2A) for subsequent deposition of distinct functional conductive and semiconducting layers, as shown in the cross-sectional SEM images and EDS maps in FIG. 2B. With this low-temperature seed layer, the growth of continuous conductive films was achieved across a wide range of temperatures up to and slightly above the T_{g} of the acrylate polymer lattices used herein (172° C.). In addition, this seed layer can enable the growth of conductive films on 3D parts printed from various commercial SLA polymer resins, indicating that this process is applicable to a range of acrylate and epoxy photopolymers.

The 3D lattice structures were produced by microstereolithography using a MicroArch S240 3D-printer from Boston Microfabrication (BMF) with pixel size ranging from 2 μm to 10 μm and layer thickness of 10 μm. The 3D structures for fabricated using a highly rigid and thermally stable polyurethane acrylate resin (‘HTL’) developed by BMF with a T_{g} of 172° C., a tensile strength of 79.3 MPa, and resin viscosity of 85 cP. ALD film growth was performed on an Anric AT-400 system at temperatures from 100° C. to 175° C. using trimethylaluminum (TMA), diethylzinc (DEZ), and tetrakis(dimethylamino)tin(IV) (TDMA-Sn). Growth of films from 5 nm-100 nm were performed using 40 sccm N₂ flow and a nominal chamber pressure of 130 mT, completing a varied number of cycles. One complete ALD cycle consisted of three pulses of DEZ/TMA/TDMA-Sn and two oxidant pulses (H₂O for TMA/DEZ and O₃ for TDMA-Sn). To produce AZO, ZnO films were doped with 5 at. % Al₂O₃ by using a ratio of 19:1 cycles of ZnO:Al₂O₃. The TDMA-Sn precursor was heated to 70° C. to increase its vapor pressure. All 3D-printed microlattices were developed using the BMF HTL resin in yellow. In addition to this resin, the seed layer process disclosed herein can also work for parts made with the BMF HTL resin in black, CADworks 3D MiiCraft BV-007A Microfluidics resin, Kudo 3D UHR resin, Formlabs Rough 4000 resin, Formlabs Tough 2000 resin, Formlabs High Temp resin, and other resins.

Conformal Au electrodes (20 nm thick) for measurements of the 3D structures were deposited by sputtering (Hummer) and physically masking the channel area with a thin polyimide (Kapton) tape with acrylic adhesive. The tape was removed to reveal masked 3D channels through the lattice structures with critical dimensions from 1 mm to 4 mm in length. DC electrical measurements (B2902A) were performed on a semiconductor probe station using tungsten needle probes to contact the 3D structures (FIG. 15) or Cu metal pads that are touching the electrodes.

The use of the Au metal contacts ensured measurement variability of less than 2% (FIG. 15). Batch-to-batch variability of resistance across multiple 3D lattices was measured to be approximately ±10%. The study of 3D lattice resistance for variable SnO₂ coating thicknesses (FIG. 3C) was performed through ALD growth of incrementally thicker layers. The seed layer was deposited, followed by the first increment of SnO₂, after which sputtered gold electrodes were deposited to facilitate precise measurements. Thicker SnO₂ films were coated onto this structure for subsequent measurements.

SEM/EDS analysis was performed with a Thermo Fisher Scientific Helios 5 CX DualBeam SEM. XRD studies were performed on the coated 3D and 2D structures using a Rigaku Ultrax-18 system with a Cu Ku line source with a step size of 0.01°. XPS analysis was performed with a Kratos Axis Supra.

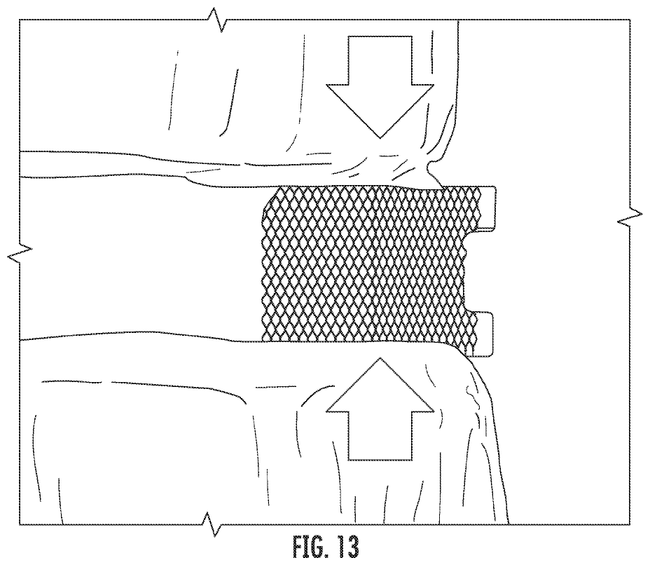

Gas sensing measurements were conducted using dry air for purging a closed chamber. VOCs were dosed as liquids (ethanol, isopropanol, or acetone) onto a Peltier heating element while the resistance of the cube and a 2D film on SiO₂ were simultaneously measured with a B2902A source meter. Self-heating experiment was conducted by driving a current across the cube and measuring the cube temperature with a FLIR E60 IR camera. Anemometers were characterized in a flow through mode, using a ⅜ inch tubing. Cube response to different air temperatures was measured by monitoring the resistance change across the cube as the temperature of the cube was changed with the cube resting in an oven during measurement. Air temperature response of cubes was measured with cube sitting at the outlet of a ⅜ inch tubing with a flow rate of 20 lpm. The sensor lattices were attached to 28-gauge Cu wire and suspended in the tubing throughout the measurement. A flow meter was used to set a known air flow rate through the channel. The pressure sensors were tested under compression mode with a mechanical testing system (Pasco ME-8236) while logging the resistance measured in the direction of compressive loading (FIG. 13).

The estimated resistance of the cubic volumes of octet lattice plotted in FIGS. 3C and 3D were computed in MATLAB by using a weighted Laplacian representation of the octet lattice, as disclosed in the embodiments herein. The graph object is generated based on the exact geometry of the octet truss system. Each beam is represented with an edge in the graph, which has a corresponding weight (conductance) given by its resistance, as calculated by Eq. (1) and the methods disclosed herein using the measured sheet resistance data. Calculation of the pseudo-inverse of the weighted Laplacian allows efficient computation of the effective resistance between any two points. To match the experimental conditions for the cubic structures with sputtered electrodes, the simulation adjusts the conductance weights for the faces coated in Au to match the predicted conductivity for a 20 nm sputtered Au coating. Simulations were conducted for cubic volumes as well as higher aspect ratio structures as shown in FIG. 3D to extract a resistance per cube.

### Example 2

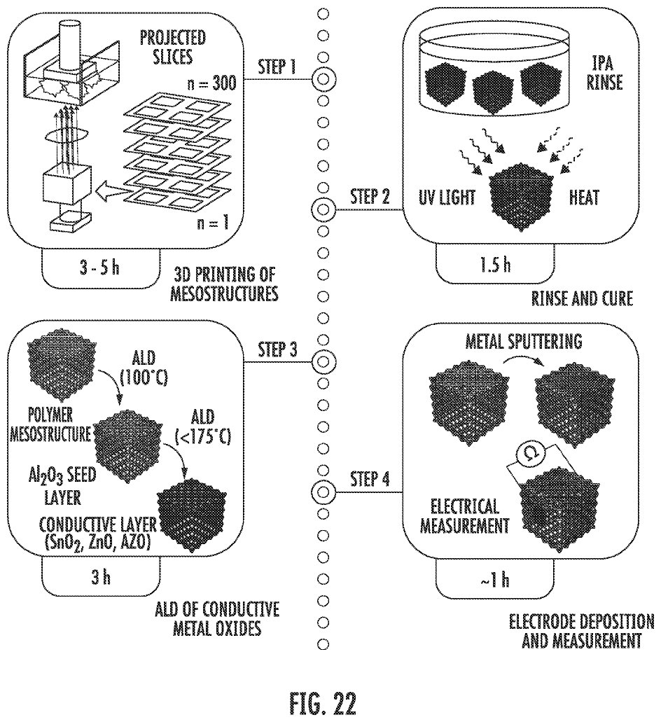

Additive manufacturing (AM) three-dimensional (3D) mesostructures can be designed to enhance mechanical, thermal, or optical properties, driving future device applications at the micron to millimeter scale. AM mesostructures can be transformed into 3D electronics by growing nanoscale conducting films on 3D-printed polymers. Precision thermal ALD can be used with conducting, semiconducting, and dielectric metal oxides. This can be applied to ultrasmooth, customizable photopolymer lattices printed by high-resolution microstereolithography. This process is shown in FIGS. 22-24.

Additive manufacturing can be accomplished through a variety of fabrication methods. This protocol uses microstereolithography (μSLA) to print AM mesostructures that serve as polymer templates for deposition of nanoscale conductive materials by thermal atomic layer deposition (ALD). This example deposits nanoscale Al₂O₃, SnO₂, ZnO, and aluminum doped (5 wt. %) zinc oxide (AZO). The insulating Al₂O₃ film can be used as a dielectric or a seed layer for other material growths. As a seed layer, the Al₂O₃ allows for deposition of conductive (SnO₂) and/or semiconductive (ZnO, AZO) materials. Without this seed layer, ALD growth of conducting/semiconducting materials is inhibited on photopolymer materials. This process can be expanded to other photopolymer materials and ALD oxide coatings beyond those employed herein (including structures printed with other 3D printers), allowing conversion of AM mesostructures into devices with potential applications in energy storage, sensing, and microrobotics.

Additionally, other metal organic precursors (e.g., TiCl₄, HfCl₄, tris (dimethylamino) silane (TDMAS)) could be used for this process if the thermal ALD process can be performed at temperatures below the glass transition (T_{g}) of the 3D-printed polymer.

Instead of gold electrodes, it is also possible to sputter other metals (e.g., Cu, Ag, Pt) to use as contacts.

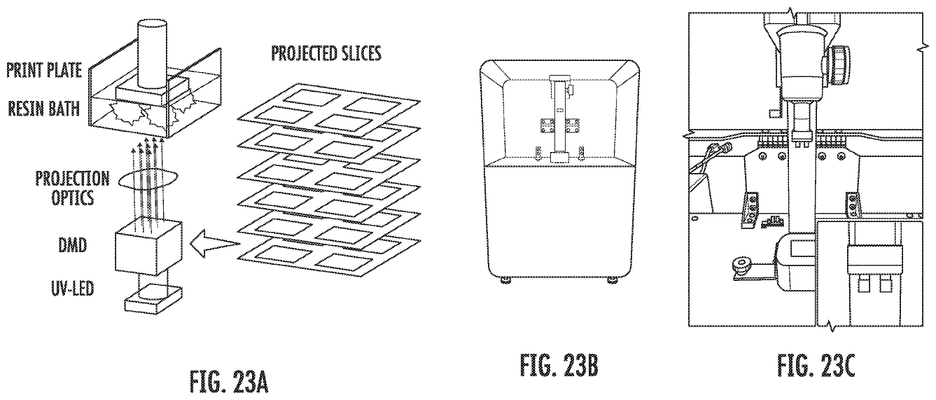

Microstereolithography (μSLA) is a high-resolution 3D printing process that allows for fabrication of mesoscale structures with beam sizes in the range from 10 μm-1 mm, shown in FIG. 23A.

Printing parts without supports is possible if the part is strong enough to support itself during the print. Small features connecting larger features may be failure points, so using supports can provide extra strength to ensure print success. Additionally, using supports can decrease the risk of damaging a part when removing it from the build plate. However, these conditions can be adjusted as necessary

Thermal ALD allows for growth of conductive materials on the external and internal facets of a given 3D-printed structure. The following steps outline a process for deposition of conductive materials on AM 3D polymer structures that can be printed by lower cost, high throughput stereolithography processes. The tailored thickness of an ALD film allows precise control of the electrical properties of these coatings.

Control substrates can optionally be prepared for confirmation of growth of the conductive material. Small pieces of silicon wafers may be used to later measure deposited thickness, either with ellipsometry or etched and measured with stylus profilometry. Additionally, small pieces of silicon dioxide coated silicon wafers may be used to measure sheet resistance of deposited material with a four-point probe.

Deposition of a thicker seed layer is possible if desired or necessary, but a base of at least 100 cycles (approximately 10 nm) can ensure later growth of conductive materials.

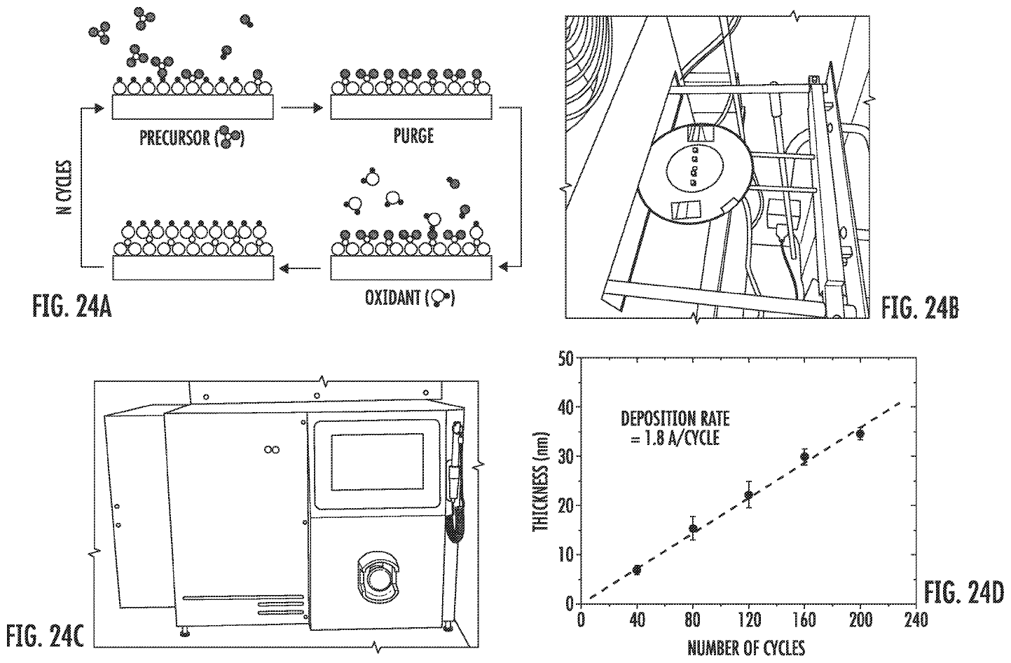

The deposition rate can vary slightly for different ALD machines or as a precursor is used and the vapor pressure decreases. The total number of cycles (FIG. 24D), the deposition temperature, and the precursors can be modified to achieve the desired conductivity of the material. Air flow in the chamber can also cause non-uniformities in deposited thickness.

Printing resolution may be limited by the pixel size used in the μSLA process and the maximum size of conductive 3D parts may be limited by the volume of the ALD chamber. The thickness of the deposited material can be limited due to the cyclic nature of the ALD process. Films may need to be thicker than 5 nm in order to ensure uniform coverage on the 3D polymer mesostructure. Films thicker than 100 nm are possible, but require deposition times of several hours or longer. ALD can be difficult to use with mm-scale films because deposition time scales with cycle count, taking 30-35 seconds per cycle. Growths of coatings 100 nm or thinner can be completed within several hours but, if thicker (1 mm) films are desired, another method for deposition may be more suitable. The process used herein has been proven successful between 80° C.-175° C. Higher deposition temperatures with this resin will exceed the glass transition temperature, which can inhibit growth of continuous and conductive films. However, higher temperature deposition is possible with resins that have higher T_{g}. Lower deposition temperatures may be possible with this resin as well and would be desirable for soft polymers that have much lower T_{g}. However, lower temperature depositions can result in more amorphous films with lower conductivity.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A device comprising:
a polymer structure, wherein the polymer structure is a complex device in three dimensions;
a seed layer on the polymer structure, wherein the seed layer is an oxide, a nitride, or an oxynitride; and
a thin film disposed on the seed layer.

2. The device of claim 1, wherein the polymer structure is 3D printed.

3. The device of claim 1, wherein the thin film is a metal oxide.

4. The device of claim 3, wherein the thin film is at least one of ZnO, SnO₂, Al₂O₃, AZO, In₂O₃, TiO₂, LiOₓ, GaOₓ, AgOₓ, NiOₓ, WOₓ, or CoOₓ.

5. The device of claim 3, wherein the thin film is at least one of InZnOₓ, InGaOₓ, InGaZnO, SnZnOₓ, SnGaOₓ, InSnGaOₓ, or InSnZnOₓ.

6. The device of claim 1, wherein the thin film is at least one of In₂O₃:Sn, SnO₂:Sb, SnO₂:F, CdO:Al, or CdO.

7. The device of claim 1, wherein the thin film is at least one of SiN, AlN, HfN, ZrN, TaN, or YN.

8. The device of claim 1, wherein the seed layer is at least one of Al₂O₃, SiO₂, ZrO₂, HfO₂, Y₂O₃, GeOₓ, La₂O₃, SiN, AlN, HfN, ZrN, TaN, or YN.

9. The device of claim 1, wherein the thin film is a dielectric, semiconductor, or conductor.

10. The device of claim 1, wherein the seed layer is configured as a barrier to subsurface diffusion into the polymer structure.

11. The device of claim 1, wherein the thin film has a thickness less than 5 nm.

12. The device of claim 1, wherein the thin film has a thickness from 2 nm to 500 nm.

13. The device of claim 1, wherein the seed layer has a thickness from 5 nm to 200 nm.

14. The device of claim 1, wherein the polymer structure includes acrylated polyurethane, bisphenol A glycerolate (1 glycerol/phenol) diacrylate (BPAGDA), poly(ethylene glycol) diacrylate (PEGDA), polymer pentaerythritol tetraacrylate (PETA), epoxy based resins, or methacrylic acid resins.

15. The device of claim 1, wherein the thin film and the seed layer are disposed on less than an entirety of the polymer structure.

16. The device of claim 1, wherein the thin film and the seed layer are disposed an entirety of the polymer structure.

17. The device of claim 1, wherein the polymer structure is a lattice structure.

18. The device of claim 1, wherein the polymer structure is a cantilever or beam.

19. The device of claim 1, wherein the polymer structure has an irregular cross-sectional geometry.

20. The device of claim 1, wherein the polymer structure has feature dimensions of less than 10 μm.

21. The device of claim 1, wherein the polymer structure has feature dimensions from 10 μm to 3 cm.

22. The device of claim 1, wherein the polymer structure has 50% to above 90% volume porosity.

23. A method comprising:
3D printing a polymer structure, wherein the polymer structure is a complex device in three dimensions; and
forming a conformal thin film on the polymer structure, wherein the forming includes:
depositing a seed layer on the polymer structure, wherein the seed layer provides a planarized adhesion layer, and wherein the seed layer is an oxide, a nitride, or an oxynitride; and
depositing a thin film on the seed layer using atomic layer deposition.

24. The method of claim 23, wherein the thin film is deposited at a temperature from 30° to above 330° C.

25. The method of claim 24, wherein the thin film is deposited at a temperature from 60° to 200° C.

26. The method of claim 25, wherein the thin film is deposited at a temperature from 60° to 100° C.

27. The method of claim 24, wherein the temperature is approximately 100° C.

28. The method of claim 23, wherein the thin film is a metal oxide.

29. The method of claim 28, wherein the thin film is at least one of at least one of ZnO, SnO₂, Al₂O₃, AZO, In₂O₃, TiO₂, LiOₓ, GaOₓ, AgOₓ, NiOₓ, WOₓ, or CoOₓ.

30. The method of claim 28, wherein the thin film is at least one of InZnOₓ, InGaOₓ, InGaZnO, SnZnOₓ, SnGaOₓ, InSnGaOₓ, or InSnZnOₓ.

31. The method of claim 23, wherein the thin film is at least one of In₂O₃:Sn, SnO₂:Sb, SnO₂:F, CdO:Al, or CdO.

32. The method of claim 23, wherein the thin film is at least one of SiN, AlN, HfN, ZrN, TaN, or YN.

33. The method of claim 23, wherein the seed layer is at least one of Al₂O₃, SiO₂, ZrO₂, HfO₂, Y₂O₃, GeOₓ, La₂O₃, SiN, AlN, HfN, ZrN, TaN, or YN.

34. The method of claim 23, wherein the thin film is a dielectric, semiconductor, or conductor.

35. The method of claim 23, wherein the seed layer is configured as a barrier to subsurface diffusion into the polymer structure.

36. The method of claim 23, wherein the thin film has a thickness less than 5 nm.

37. The method of claim 23, wherein the thin film has a thickness from 2 nm to 500 nm.

38. The method of claim 23, wherein the seed layer has a thickness from 5 nm to 200 nm.

39. The method of claim 23, wherein the polymer structure includes acrylated polyurethane, bisphenol A glycerolate (1 glycerol/phenol) diacrylate (BPAGDA), poly(ethylene glycol) diacrylate (PEGDA), polymer pentaerythritol tetraacrylate (PETA), epoxy based resins, or methacrylic acid resins.

40. The method of claim 23, wherein the thin film and the seed layer are disposed on less than an entirety of the polymer structure.

41. The method of claim 23, wherein the thin film and the seed layer are disposed an entirety of the polymer structure.

42. The method of claim 23, wherein the polymer structure is a lattice structure, a cantilever, or a beam.

43. The method of claim 23, wherein the polymer structure has an irregular cross-sectional geometry.

44. The method of claim 23, wherein the polymer structure has feature dimensions of less than 10 μm.

45. The method of claim 23, wherein the polymer structure has feature dimensions from 10 μm to 3 cm.

46. A device produced using the method of claim 23.

47. The device of claim 46, wherein the device is a gas sensor, anemometer, strain sensor, or thermistor.
